(19) United States
(12) Patent Application Publication
(10) Pub. No.: US 2026/0344116 A1
(43) Pub. Date: Oct. 29, 2026

(54) VERTICAL STACKED MICRODISPLAY PANEL AND MANUFACTURING METHOD THEREOF

(71) Applicant: WAVELORD CO., LTD, Hwaseong-si (KR)

(72) Inventors: Juneo SONG, Suwon-si (KR); Ji Hyung MOON, Gunpo-si (KR); Tae Kyoung KIM, Osan-si (KR)

(73) Assignee: WAVELORD CO., LTD, Hwaseong-si (KR)

(21) Appl. No.: 19/404,043

(22) Filed: Dec. 1, 2025

(30) Foreign Application Priority Data
Dec. 3, 2024 (KR) 10-2024-0177195
Mar. 4, 2025 (KR) 10-2025-0027426

(51) Int. Cl. H10H 20/813; H10H 20/01; H10H 20/857; H10H 29/01

(52) U.S. Cl. CPC H10H 20/8131; H10H 20/017; H10H 20/0364; H10H 20/857; H10H 29/012; H10H 29/032

(57) ABSTRACT

The present invention relates to a vertically stacked microdisplay panel including: a back wafer in which a plurality of complementary metal-oxide semiconductor (CMOS) electrode pads are aligned on an upper surface; a plurality of light-emitting diode (LED) stacks, each of which includes at least one light-emitting portion and is aligned on a corresponding one of the plurality of CMOS electrode pads; and a common electrode formed on the plurality of LED stacks, wherein, when the LED stacks include the plurality of light-emitting portion, the plurality of light-emitting portions are bonded through a bonding layer and stacked in a vertical direction, and when the plurality of light-emitting portions are bonded through the bonding layer, each of the LED stacks emits only a specific color by blocking light generated from a lower light-emitting portions with the bonding layer.

### CROSS-REFERENCE TO RELATED APPLICATION

This application claims priority to and the benefit of Korean Patent Application No. 10-2024-0177195, filed on Dec. 3, 2024, and Korean Patent Application No. 10-2025-0027426, filed on Mar. 4, 2025, the disclosure of which is incorporated herein by reference in its entirety.

### BACKGROUND

### 1. Field of the Invention

The present invention relates to a vertically stacked microdisplay panel and a method of manufacturing the same, and more particularly, to a vertically stacked light-emitting diode on silicon (LEDoS) microdisplay panel without the need for an alignment process of LED stacks and complementary metal-oxide semiconductor (CMOS) electrode pads due to the use of an engineering monolithic epitaxy wafer method, and a method of manufacturing the same.

### 2. Discussion of Related Art

The types of implementations of the metaverse, which has recently been attracting attention, are classified into four types of virtual reality (VR), augmented reality (AR), mixed reality (MR), and extended reality (XR). The metaverse ecosystem is expected to develop in the future focusing on XR, which is a reality that combines VR, AR, and MR among these. In addition, in order to implement this effectively, devices (smart glasses, head-mounted displays, and the like) that include microdisplays with a diagonal length of less than one inch as a core component, along with software for next-generation computing platforms that can deliver innovative user experiences, are required. Particularly, the development of high-performance microdisplay panel technology is absolutely necessary to provide XR users with the greatest immersion, visibility, and convenience and minimize dizziness.

As shown in FIG. 1, a microdisplay panel 10 according to the related art corresponds to a technology that combines a silicon complementary metal-oxide-semiconductor (Si CMOS) semiconductor wafer process and a high-resolution, high-brightness, ultra-small display process, and the microdisplay panel 10 according to the related art may have a structure in which a Si CMOS wafer 11 of 4″ or more that has a (100) crystal plane and includes a plurality of CMOS electrode pads 12, a plurality of microLED electrode pads 14, and a transparent wafer 13 of 4″ or more that includes a plurality of microLED chips 15 are bonded through conductive bonding 16. Meanwhile, the types of microdisplay panels expected to be applied to XR devices include liquid crystal (LC)-based LC on Si (LCoS), organic light-emitting diode (OLED)-based OLED on Si (OLEDoS), and ultra-small microLED-based LED on Si (LEDoS) with a pixel size of less than 5 μm. In addition, in the case of VR, where displays with a low pixel density are applied, microdisplay panels are being developed and mass-produced mainly based on LCoS and OLEDoS.

However, with the advancement of metaverse implementation technology, the need for lightweight AR, MR, and XR devices to which microdisplay panels with a high pixel density are applied is gradually increasing. In addition, although the development of LEDoS technology, which is considered an ideal solution in theory based on its superior inorganic properties, is urgently needed to satisfy these needs, a microdisplay panel platform for this has not yet been established.

LEDoSs based on ultra-small microLEDs with pixel sizes of less than 5 um have the advantages of an excellent power-to-performance ratio (P/P) and a short response speed when applied to XR devices, and there are the advantages that the LEDoSs include inorganic materials and thus have a long lifetime, and have efficient power use to reduce heat generation and enable long-term battery life. Particularly, since XR devices have a very short distance between the display and the eyes, even a slight delay in image conversion can easily cause discomfort such as dizziness. Thus, LEDoS, which has a nanosecond response speed, is considered to be the most suitable for XR devices compared to LCoS and OLEDoS, which have a microsecond response speed.

Furthermore, it is evaluated that the biggest reason why LEDoS is attracting attention in AR, MR, and XR devices, unlike VR, is due to its brightness and luminous efficiency. Since smart glasses can be worn in any location, high brightness is essential for normal operation even in outdoor environments such as in sunlight. In theory, microLEDs support brightness of tens to millions of nits, and since OLEDs are made of organic materials, whereas microLEDs are made of inorganic materials, the microLEDs also have the advantage of high luminous efficiency.

However, despite the above-described advantages, the biggest reason why LEDoSs based on ultra-small microLEDs with pixel sizes of less than 5 μm have not been established as a major component of XR devices is the difficulty in mass production. That is, since the LEDoS requires millions of ultra-small microLEDs to be fixed on a Si CMOS wafer, the process difficulty is high and the yield is very low, which leads to increased manufacturing costs and high component prices. This is reflected in the final consumer price, and it is difficult to satisfy market demand when LEDoSs are supplied as high-priced XR devices.

Meanwhile, as shown in FIG. 2, the development of LEDoS to which group III-V compound (GaN, GaP, and the like) microLED light sources are applied has been in progress until recently through traditional approaches such as (1) monolithic integration of wafers (or unit dies) including microLED arrays on wafers or (2) hybridization between wafers (or unit dies) on blue, green, and red light source wafers (or unit dies) on which wafers or microLED arrays are fabricated.

One of the biggest obstacles to the development of LEDoS to which blue, green, and red microLED light sources including group III-V compounds are applied is the difficulty in securing a solution for pixels smaller than 5 μm. In addition, recently, 5 μm-level pixels have been successfully demonstrated using monolithic integration technology, and some demonstrators developed based on hybridization technology were fabricated using sapphire flip chips, achieving 10 μm-level pixels. Additionally, it has been demonstrated that it is possible to reduce pixels to the 5 μm level in the same way due to the use of micro tube wiring in hybridization technology. However, both monolithic integration and hybridization technologies are impractical solutions with significant challenges in mass production in terms of quality and yield, making mass production difficult.

The above-described monolithic integration technology and hybridization technology have a common feature of separately designing and manufacturing a front plane wafer including a group III-V compound microLED array and a Si CMOS back plane wafer including numerous IC electrode pad arrays and then assembling these wafers. However, the microLED array manufactured at the unit die level or wafer level on the Si CMOS wafer needs to be ultra-finely aligned regardless of the method. Thus, in this case, alignment is limited to the precision of the process-related device, which has a significant impact on the pixel and inter-pixel distance (pitch) limitations, and mass production also becomes difficult. Accordingly, a new alternative solution that is capable of overcoming the above-described ultra-fine alignment constraints is required to manufacture LEDoS to which high-resolution, high-brightness, and high-speed operating blue, green, and red microLED light sources with pixels of less than 5 μm and pitches of less than 3 μm are applied.

Accordingly, although several impressive demonstrations with 6 μm pixels have been recently released using engineering monolithic epitaxy wafers manufactured through a low-temperature metal bonding process between a Si CMOS wafer and a microLED array wafer, mass production is considered impossible due to low quality and yield issues caused by low-temperature metal bonding and the use of small-diameter wafers of less than 6 inches. Above all, when fabricating ultra-fine pixels of less than 3 μm for microdisplays using engineering monolithic epitaxy wafers according to the related art using metal bonding, the patterning etching process faces even greater difficulties.

As another example, great progress has been made in solving the problem of limitations on the brightness and resolution of LEDoS to which group III-V compound microLED light sources have been recently applied, and a novel engineering monolithic epitaxy wafer approach has been proposed that can provide high-volume, low-cost manufacturing solutions using 12-inch large-diameter Si CMOS wafers.

As shown in FIG. 3, the corresponding technology is specifically performed through the following four-step process using an engineering monolithic epitaxy wafer. (1) First, an LED epitaxy cut to a predetermined size (for example, 4 mm×6 mm) is aligned and bonded at a unit die level on a 12-inch large-diameter Si blanket wafer using an LED epitaxy wafer. Afterward, the growth wafer and buffer layer of the LED epitaxy are removed and then planarized to leave only an LED active layer of a predetermined thickness (for example, approximately 1.5 μm) on the large-diameter Si blanket wafer, and then the LED FAB process on the form of a pixel chip is completed. (2) Subsequently, the Si blanket wafer with the completed pixel chip is bonded to a 12-inch CMOS IC Si wafer at the wafer level through multi-layer metal bonding. (3) Subsequently, the Si blanket wafer is removed. (4) Subsequently, the remaining process is finally performed on the CMOS IC Si wafer for the microLED array that functions as a pixel.

However, in operation (1), when bonding the LED epitaxy unit die on the Si blanket wafer, there is a limitation that the alignment needs to be performed on a CMOS IC Si wafer of the same size to bond the LED epitaxy unit die on the Si blanket wafer. In addition, in operation (2), when bonding with a multi-layer metal including a low-melting-point metal (Sn or In), there is a problem in that a phenomenon of overflowing low-melting-point metal components occurs relatively easily, resulting in a short circuit defect that is electrically connected between the microLED sub-pixel arrays in the panel or with the adjacent CMOS IC electrode pad array. Furthermore, in operation (2), there is a problem that defects occur due to the difficulty in ultra-fine alignment wafer bonding between the Si blanket wafer (that is, the front plane wafer) and the CMOS IC Si wafer due to the optically opaque nature of the Si blanket wafer and the multi-layer metal bonding layer. Here, the ultra-fine alignment means aligning the microLED array, which is a plurality (hundreds to tens of millions) of ultra-small pixel chips provided on a Si blanket wafer, and the CMOS IC electrode pad array provided on a CMOS IC Si wafer in a 1:1 manner.

That is, although the engineering monolithic epitaxy wafer approach presented in the above-described technologies is evaluated to provide a solution that brings us one step closer to the implementation of LEDoS based on ultra-small microLEDs with pixel sizes of less than 5 μm, since there are quality and yield issues caused by the use of metals (low temperature, multi-layer) in wafer bonding, it is very difficult to manufacture high-resolution microdisplays with ultra-fine pixels smaller than 3 μm, and there are also problems with some alignment processes, new alternatives are needed.

In addition, since color filters are still applied to the vertically stacked tandem structures of conventional microdisplays so that full color is implemented, there are disadvantages in terms of color quality, process complexity, and productivity.

### RELATED ART DOCUMENTS

### Patent Document

(Patent Document 0001) Korean Laid-Open Patent Publication No. 10-2018-0009116

### SUMMARY OF THE INVENTION

The present invention is directed to solving the above-described conventional problems and providing a vertically stacked light-emitting diode on silicon (LEDoS) microdisplay panel and a manufacturing method thereof without the need for an alignment process of LED stacks and complementary metal-oxide semiconductor (CMOS) electrode pads due to the use of an engineering monolithic epitaxy wafer method, to which general metal bonding is applicable.

According to an aspect of the present invention, there is provided a vertically stacked microdisplay panel including: a back wafer in which a plurality of complementary metal-oxide semiconductor (CMOS) electrode pads are aligned on an upper surface; a plurality of LED stacks, each of which includes at least one light-emitting portion and aligned on a corresponding one of the plurality of CMOS electrode pads; and a common electrode formed on the plurality of LED stacks, wherein, when the LED stacks include the plurality of light-emitting portions, the plurality of light-emitting portions are bonded through a bonding layer and stacked in a vertical direction, and when the plurality of light-emitting portions are bonded through the bonding layer, each of the LED stacks emits only a specific color by blocking light generated from a lower light-emitting portion with the bonding layer.

Also, the bonding layer may be formed of an opaque conductive material.

In addition, the plurality of LED stacks may include a first LED stack for emitting only a first color, a second LED stack for emitting only a second color, and a third LED stack for emitting only a third color.

Furthermore, the common electrode may be a positive electrode or a negative electrode.

According to another aspect of the present invention, there is provided a method of manufacturing a vertically stacked microdisplay panel, which includes: a preparation operation of preparing a plurality of front wafers including a support wafer and a light-emitting portion, a temporary wafer, and a back wafer in which a plurality of CMOS electrode pads are aligned on an upper surface; a stacking operation of vertically stacking the plurality of light-emitting portions on the temporary wafer by repeatedly performing bonding of the front wafer onto the temporary wafer through a bonding layer and then removing the support wafer; a bonding operation of bonding the plurality of stacked light-emitting portions onto the back wafer and then stacking the plurality of light-emitting portions on the back wafer by removing the temporary wafer; an etching operation of separating the plurality of stacked light-emitting portions into predetermined units by etching the plurality of light-emitting portions to align a plurality of LEDs on the plurality of CMOS electrode pads; a removal operation of selectively removing the light-emitting portion of each of the LED stacks; and a forming operation of forming a common electrode on the plurality of LED stacks, wherein, when the plurality of light-emitting portions are bonded through the bonding layer, each of the LED stacks emits only a specific color by blocking light generated from a lower light-emitting portion with the bonding layer.

Also, the bonding layer may be formed of an opaque conductive material.

In addition, the plurality of LED stacks may include a first LED stack for emitting only a first color, a second LED stack for emitting only a second color, and a third LED stack for emitting only a third color.

Furthermore, the common electrode may be a positive electrode or a negative electrode.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 shows the structure of a microdisplay panel according to the related art;

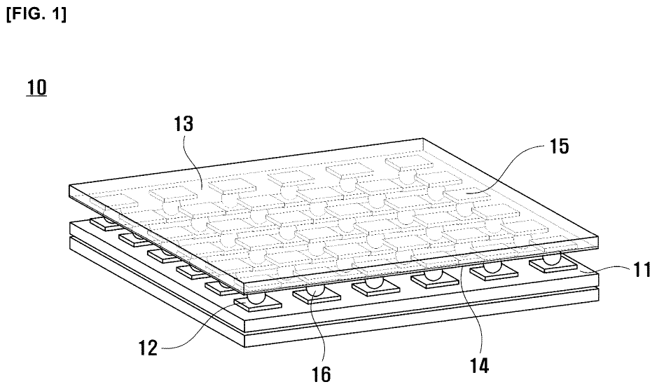

FIG. 2 shows a light-emitting diode on silicon (LEDoS) development approach according to the related art;

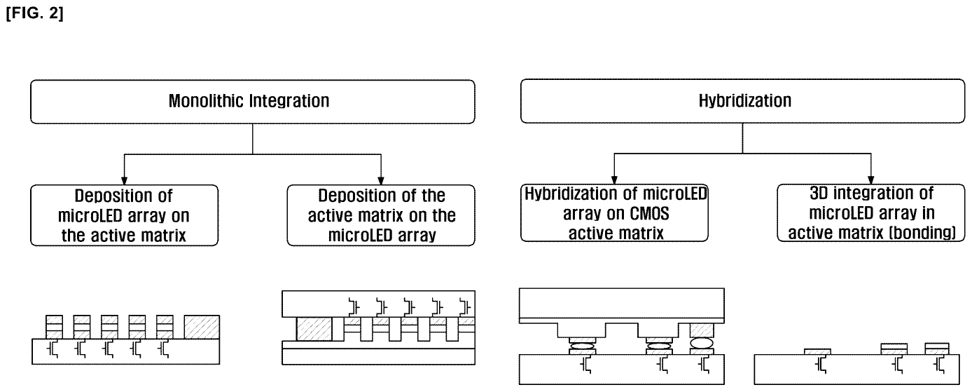

FIG. 3 shows an approach using a conventional engineering monolithic epitaxy wafer according to the related art;

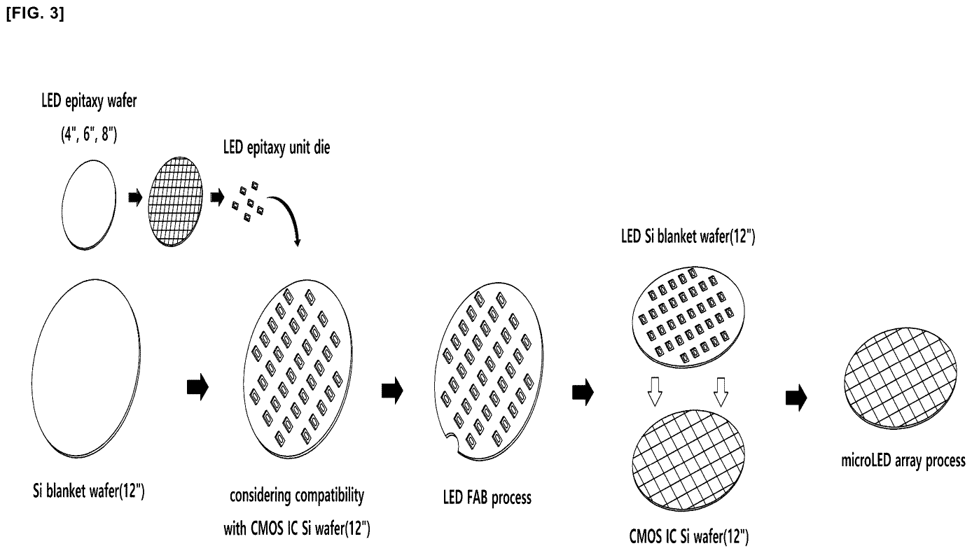

FIG. 4 is a flowchart of a method of manufacturing a vertically stacked microdisplay panel according to one embodiment of the present invention;

FIG. 5 shows a process of preparing a front wafer in a p-side up form in the method of manufacturing a vertically stacked microdisplay panel according to one embodiment of the present invention;

FIG. 6 shows a process of preparing a front wafer in an n-side up form in the method of manufacturing a vertically stacked microdisplay panel according to one embodiment of the present invention;

FIG. 7 shows a process of preparing a back wafer in the method of manufacturing a vertically stacked microdisplay panel according to one embodiment of the present invention;

FIGS. 8 and 9 show a process of manufacturing a vertically stacked microdisplay panel according to the method of manufacturing a vertically stacked microdisplay panel according to one embodiment of the present invention; and

FIG. 10 shows a vertically stacked microdisplay panel according to one embodiment of the present invention.

### DETAILED DESCRIPTION OF EXEMPLARY EMBODIMENTS

Hereinafter, some embodiments of the present invention will be described in detail with reference to the following exemplary drawings. In assigning reference numerals to the components of each drawing, it is important to note that the same component should have the same numeral as far as possible, even when it appears on different drawings.

Further, in describing embodiments of the present invention, detailed descriptions of relevant disclosed configurations or features are omitted when it is determined that such detailed descriptions would impede an understanding of the embodiments of the present invention.

Further, in describing the components of embodiments of the present invention, terms such as first, second, A, B, (a), (b), and the like may be used. These terms are only intended to distinguish one component from another, and the nature, order, sequence, and the like of the component are not limited by these terms.

Hereinafter, a method S100 of manufacturing a vertically stacked microdisplay panel according to one embodiment of the present invention will be described in detail with reference to the attached drawings.

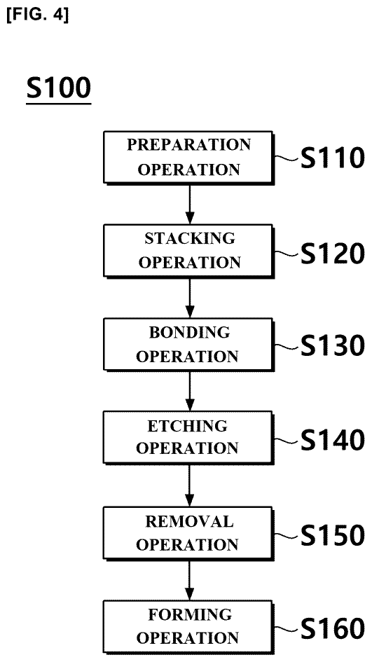

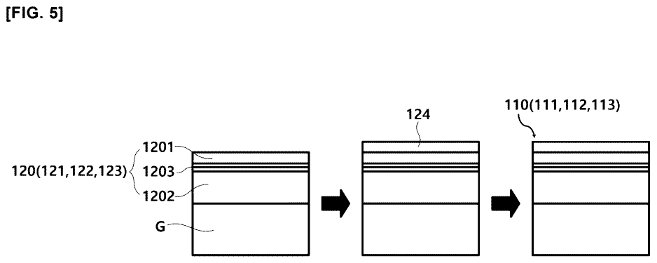

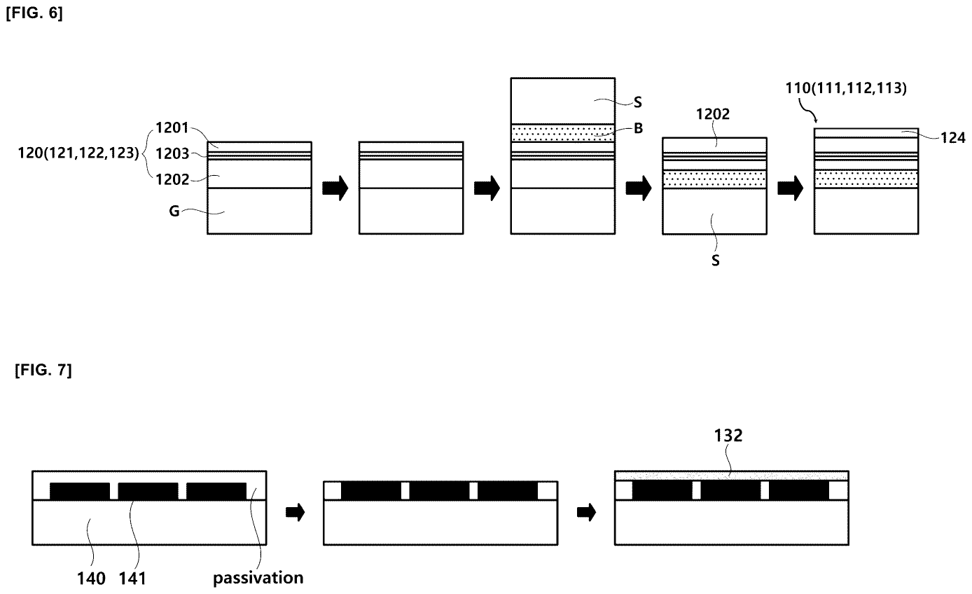

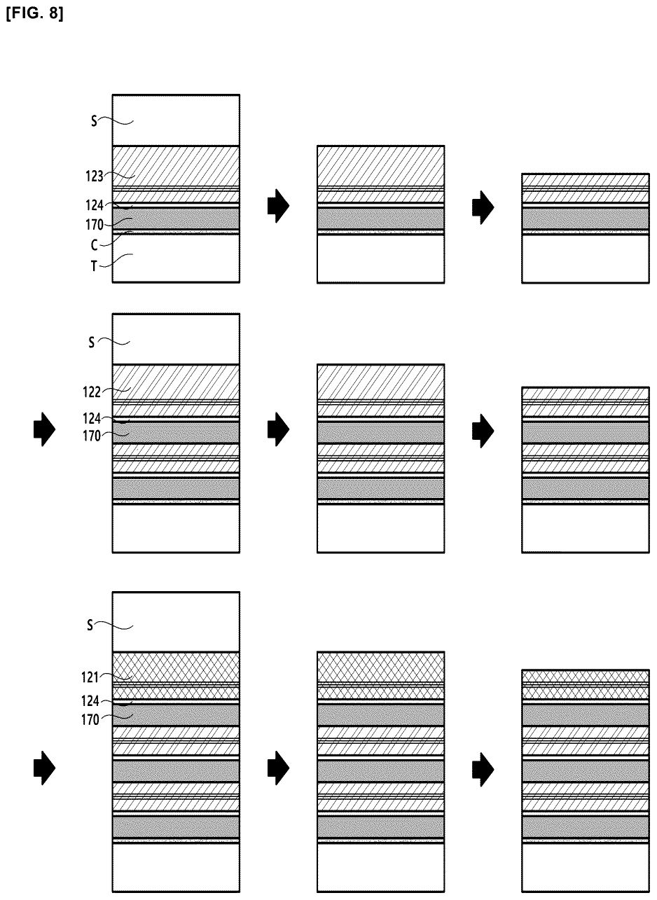

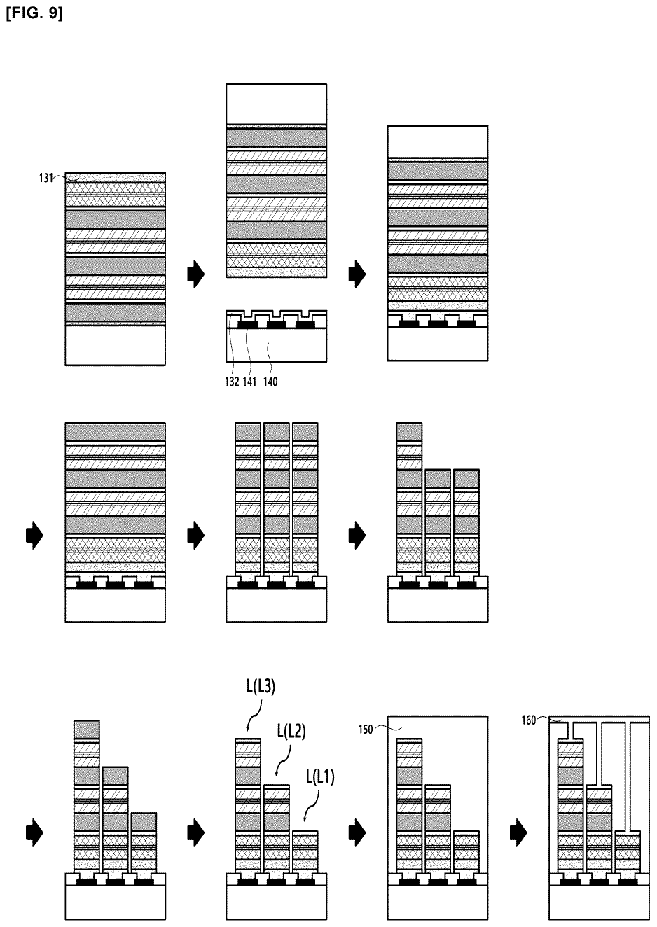

FIG. 4 is a flowchart of a method of manufacturing a vertically stacked microdisplay panel according to one embodiment of the present invention, FIG. 5 shows a process of preparing a front wafer in a p-side up form in the method of manufacturing a vertically stacked microdisplay panel according to one embodiment of the present invention, FIG. 6 shows a process of preparing a front wafer in an n-side up form in the method of manufacturing a vertically stacked microdisplay panel according to one embodiment of the present invention, FIG. 7 shows a process of preparing a back wafer in the method of manufacturing a vertically stacked microdisplay panel according to one embodiment of the present invention, and FIGS. 8 and 9 show a process of manufacturing a vertically stacked microdisplay panel according to the method of manufacturing a vertically stacked microdisplay panel according to one embodiment of the present invention.

As shown in FIGS. 4 to 9, the method S100 of manufacturing a vertically stacked microdisplay panel according to one embodiment of the present invention may include a preparation operation S110, a stacking operation S120, a bonding operation S130, an etching operation S140, a removal operation S150, and a forming operation S160.

The preparation operation S110 is an operation of preparing a plurality of front wafers 110, a temporary wafer T, and a back wafer 140.

The plurality of front wafers 110 are each for emitting a different color, and the plurality of front wafers 110 may include a first front wafer 111 for emitting a first color, a second front wafer 112 for emitting a second color different from the first color, and a third front wafer 113 for emitting a third color different from the first and second colors. Meanwhile, the first color, the second color, and the third color may be, for example, red, green, and blue, respectively, but are not limited thereto, and may include various other colors.

Here, the first front wafer 111 may include a support wafer S and a first light-emitting portion 121 disposed on an upper portion of the support wafer S, the second front wafer 112 may include the support wafer S and a second light-emitting portion 122 disposed on an upper portion of the support wafer S, and the third front wafer 113 may include the support wafer S and a third light-emitting portion 123 disposed on an upper portion of the support wafer S.

A light-emitting portion 120 generates light and may emit blue light, green light, or red light. In the present invention, when the light-emitting portion 120 emits blue light or green light, binary, ternary, or quaternary compounds such as InN, InGaN, GaN, AlGaN, AlN, and AlGaInN, which are group III (Al, Ga, and In) nitride semiconductors among group III-V compound semiconductors, may be disposed at appropriate positions and in an appropriate order on an initial growth wafer G and epitaxially grown.

Particularly, in order to emit blue or green light, a high-quality group III nitride semiconductor such as InGaN with a high In composition needs to be preferentially formed on an upper portion of a group III nitride semiconductor including GaN, AlGaN, AlN, or AlGaInN, but is not limited thereto.

In addition, in the present invention, when the light-emitting portion 120 emits red light, binary, ternary, and quaternary compounds such as InP, InGaP, GaP, AlInP, AlGaP, AlP, and AlGaInP, which are group III (Al, Ga, and In) phosphide semiconductors among group III-V compound semiconductors, may be disposed at appropriate positions and in an appropriate order on the initial growth wafer G and epitaxially grown. In addition, in accordance with recent development of device and process technology for improving the value of display panel products, in the case of emitting red light, a high-quality group III nitride semiconductor such as InGaN with a high In composition of 30% or more, rather than a group III phosphide semiconductor, may be preferentially formed on an upper portion of a group III nitride semiconductor including GaN, AlGaN, AlN, or AlGaInN.

Particularly, in order to emit red light, a high-quality group III phosphide semiconductor such as InGaP having a high In composition needs to be preferentially formed on an upper portion of a group III phosphide semiconductor including GaP, AlInP, AlGaP, AlP, or AlGaInP, but is not limited thereto, and the group III nitride semiconductor is used as a basis for the description below.

More specifically, each of the light-emitting portions 120 may include a first semiconductor region 1201 (for example, a p-type semiconductor region), an active region 1203 (for example, multi quantum wells (MQWs)), and a second semiconductor region 1202 (for example, an n-type semiconductor region), have a structure in which the second semiconductor region 1202, the active region 1203, and the first semiconductor region 1201 are sequentially epitaxially grown on the growth wafer G, and ultimately have an overall thickness of about 5.0 to 8.0 μm typically including a plurality of layers of group III nitrides, but is not limited thereto.

Each of the first semiconductor region 1201, the active region 1203, and the second semiconductor region 1202 may be formed as a single layer or a plurality of layers. In addition, although not shown, before epitaxially growing the light-emitting portion 120 on an upper portion of the growth wafer G, necessary layers such as a buffer layer may be added to improve the quality of the epitaxially grown light-emitting portion 120. For example, the buffer layer may be configured to have a thickness of typically around 4.0 μm, including a nucleation layer NL and a compliant layer CL including an undoped semiconductor region to relieve stress and improve thin film quality. Additionally, when the growth wafer G is removed using a laser lift-off (LLO) technique, a sacrificial layer SL may be provided between the nucleation layer and the undoped semiconductor region, and a seed layer may also function as the sacrificial layer.

The second semiconductor region 1202 has a second conductivity and may be formed on the growth wafer G. The second semiconductor region 1202 may have a thickness of 2.0 to 3.5 μm.

The active region 1203 generates light by utilizing the recombination of electrons and holes and may be formed on the second semiconductor region 1202. The active region 1203 may have a thickness of several tens of nm in a plurality of layers.

The first semiconductor region 1201 has a first conductivity (p-type) and may be formed on the active region 1203. The first semiconductor region 1201 may have a thickness of several tens of nm to several μm in a plurality of layers, and the surface may have gallium polarity (Ga-polarity).

That is, the active region 1203 may be disposed between the first semiconductor region 1201 and the second semiconductor region 1202, and when holes in the first semiconductor region 1201, which is a p-type semiconductor region, and electrons in the second semiconductor region 1202, which is an n-type semiconductor region, recombine in the active region 1203, light may be generated.

Additionally, in the process of preparing the front wafer 110, an optically transparent and electrically conductive ohmic contact electrode 124 that is electrically connected to the light-emitting portion 120 by making ohmic contact with the light-emitting portion 120 may be formed on at least one of an upper surface and a lower surface of the light-emitting portion 120 that will be described below.

The support wafer S supports the light-emitting portion 120 (first light-emitting portion 121, second light-emitting portion 122, or third light-emitting portion 123) disposed on an upper portion. When an initial growth wafer G is not removed, the growth wafer G may be the support wafer S or a separate wafer bonded to remove the initial growth wafer G.

FIG. 5 shows a process for preparing a front wafer 110 in a p-side up form in the method of manufacturing a vertically stacked microdisplay panel according to one embodiment of the present invention.

As shown in FIG. 5, a process of preparing a first front wafer 111 in a p-side up form is as follows.

For the first front wafer 111 for emitting red light, a front wafer 110 in a p-side up form may be prepared by sequentially epitaxially growing a second semiconductor region 1202, an active region 1203, and a first semiconductor region 1201 on a GaAs growth wafer G, forming a p-type ohmic contact electrode 124 having transparent conductivity on an upper surface of the first semiconductor region 1201, and then forming the ohmic contact electrode 124. In this case, the growth wafer G serves as a support wafer S, and the first front wafer 111 may have a structure in which the support wafer S, a light-emitting portion 120, and the ohmic contact electrode 124 are sequentially stacked.

In addition, a process of preparing a second front wafer 112 or a third front wafer 113 in a p-side up form is as follows.

For the second front wafer 112 for emitting green light or the third front wafer 113 for emitting blue light, a front wafer 110 in a p-side up form may be prepared by sequentially epitaxially growing a second semiconductor region 1202, an active region 1203, and a first semiconductor region 1201 on a sapphire (α-phase Al2O3) growth wafer G, and then forming a p-type ohmic contact electrode 124 having transparent conductivity on an upper surface of the first semiconductor region 1201. In this case, the growth wafer G serves as a support wafer S, and the second front wafer 112 may have a structure in which the support wafer S, a light-emitting portion 120, and the ohmic contact electrode 124 are sequentially stacked.

Meanwhile, for green light and blue light, a light-emitting portion 120 for blue light or green light may be formed on a Si growth wafer G having a (111) crystal plane instead of the sapphire (α-phase Al2O3) growth wafer G, and in this case, the Si growth wafer G may be separated and removed by a mechanical polishing technique or a chemical etching technique (chemical lift-off (CLO)).

FIG. 6 shows a process of preparing a front wafer 110 in an n-side up form in the method of manufacturing a vertically stacked microdisplay panel according to one embodiment of the present invention.

As shown in FIG. 6, a process of preparing the first front wafer 111 in an n-side up form is as follows.

For the first front wafer 111 for emitting red light, a second semiconductor region 1202, an active region 1203, and a first semiconductor region 1201 may be sequentially epitaxially grown on a GaAs growth wafer G, and then a support wafer S and the first semiconductor region 1201 may be bonded through a temporary bonding layer B. Afterward, an n-side up type front wafer 110 may be prepared by separating the growth wafer G from the light-emitting portion 120 using a CLO technique, etching the second semiconductor region 1202 to reduce a thickness of the second semiconductor region 1202, and then forming an n-type ohmic contact electrode 124 having transparent conductivity on the surface of the second semiconductor region 1202 whose thickness has been reduced. In this case, the support wafer S may be formed of a Si material having a (111), (110), or (100) crystal plane, but is not limited thereto, and the first front wafer 111 may have a structure in which the support wafer S, the bonding layer B, the light-emitting portion 120, and the ohmic contact electrode 124 are sequentially stacked.

In addition, a process of preparing the second front wafer 112 or the third front wafer 113 in an n-side up form is as follows.

For the second front wafer 112 for emitting green light or the third front wafer 113 for emitting blue light, a second semiconductor region 1202, an active region 1203, and a first semiconductor region 1201 may be sequentially epitaxially grown on a sapphire (α-phase Al2O3) growth wafer G, and then a support wafer S and the first semiconductor region 1201 may be bonded through a temporary bonding layer B. Afterward, a front wafer 110 in an n-side up form may be prepared by separating the growth wafer G from a light-emitting portion 120 using a laser lift-off (LLO) technique, etching the second semiconductor region 1202 to reduce a thickness of the second semiconductor region 1202, and then forming an n-type ohmic contact electrode 124 having transparent conductivity on the surface of the second semiconductor region 1202 whose thickness has been reduced. In this case, the support wafer S may be formed of a Si material having a (111), (110), or (100) crystal plane, but is not limited thereto, and the second front wafer 112 may have a structure in which the support wafer S, the bonding layer B, the light-emitting portion 120, and the ohmic contact electrode 124 are sequentially stacked.

Furthermore, in the present invention, the materials of the growth wafer G, the support wafer S, and/or the temporary wafer T may each be silicon (Si) or sapphire, but the selection of the materials may be determined according to a wafer bonding method.

For example, in the case of bonding at room temperature through a surface activation process (surface activated bonding), wafers of different materials such as silicon (Si) or sapphire may be selected regardless of the thermal expansion coefficient. However, when wafer bonding is performed between the growth wafer G, the support wafer S, the temporary wafer T, and the back wafer 140, in a case in which bonding is performed at a temperature of 50 °C or higher, or heat treatment (annealing) is performed at a temperature of 50 °C or higher without removing one wafer while bonding between wafers is performed, wafers of the same material need to be selected.

Meanwhile, in the above-described manufacturing process of the front wafer 110, before the ohmic contact electrode 124 is formed on the surface of the first semiconductor region 1201 or the surface of the second semiconductor region 1202, in the case where the surface of the first semiconductor region 1201 is exposed (p-side up form) or the surface of the second semiconductor region 1202 is exposed (n-side up form), the surfaces may be polished and smoothly planarized through mechanical polishing (MP) or chemical-mechanical polishing (CMP) to have a smooth surface.

In addition, the ohmic contact electrode 124 of the front wafer 110 is formed of a material having transparent conductivity. When the ohmic contact electrode 124 is formed to be in contact with the first semiconductor region 1201 which is a p-type semiconductor, the material of the ohmic contact electrode 124 may include NiO, PtO, PdO, AgO2, Au, Rh2O3, RuO2, In2O3, SnO2, ZnO, IZO, ITO, and IGZO. When the ohmic contact electrode 124 is formed to be in contact with the second semiconductor region 1202 which is an n-type semiconductor, the material of the ohmic contact electrode 124 may include TiN, CrN, VN, In2O3, SnO2, ZnO, IZO, ITO, and IGZO. Furthermore, since the surface of the second semiconductor region 1202 having nitrogen polarity (N-polarity) has a much higher surface roughness than the surface of the first semiconductor region 1201 having gallium polarity (Ga-polarity), it is preferable to introduce a CMP process for polishing and flattening the surface of the second semiconductor region 1202 before forming the ohmic contact electrode 124 having transparent conductivity.

Additionally, the surface of the ohmic contact electrode 124 formed on the front wafer 110 may also be polished and smoothed through MP or CMP.

Meanwhile, when manufacturing a vertically stacked microdisplay panel 100 provided with a positive common electrode, the third front wafer 113 may have a p-side up form, the second front wafer 112 may have a p-side up form, and the first front wafer 111 may have a p-side up form. However, when manufacturing a vertically stacked microdisplay panel 100 provided with a negative common electrode, the third front wafer 113 may have an n-side up form, the second front wafer 112 may have an n-side up form, and the first front wafer 111 may have an n-side up form. However, it goes without saying that the form of each front wafer 110 may vary according to the stacking order or the like of the light-emitting portion 120.

The back wafer 140 is an active driving IC driven by an active matrix (AM) method and is a CMOS wafer in which a plurality of CMOS electrode pads 141 are arranged on an upper surface in an array, as shown in FIG. 8. A passivation layer may be formed on an upper surface of the back wafer 140 so that upper surfaces of the plurality of CMOS electrode pads 141 are not exposed, and a portion of the passivation layer may be etched so that the plurality of CMOS electrode pads 141 are exposed when the front wafer 110 is bonded.

Here, the back wafer 140 may be prepared as a Si wafer having a (100) crystal plane and may be prepared as an 8-inch or 12-inch Si wafer according to a standard CMOS IC process. However, considering that a typical LED wafer (front wafer 110) for bonding is 4 inches or 6 inches, the size of the back wafer is not particularly limited.

The stacking operation S120 is an operation of vertically stacking the plurality of light-emitting portions 120 and a bonding layer 170 on the temporary wafer T by repeatedly performing bonding of the front wafer 110 with its top and bottom reversed onto the temporary wafer T through a bonding layer 170 so that the light-emitting portion 120 of the front wafer 110 faces the temporary wafer T side, that is, so that the light-emitting portion 120 of the front wafer 110 and the temporary wafer T face each other, and then removing the support wafer S.

In this case, a separation layer C that is sacrificed and separated when the temporary wafer T is removed in the bonding operation S130 that will be described below may be formed on the temporary wafer T, and the separation layer C may include, for example, an oxide or nitride such as ITO, GaN, InGaN, AlGaN, InAlN, GaOx, GaON, ZnO, InGaZnO, InZnO, or InGaO, but is not limited thereto.

In addition, when the support wafer(S) of the front wafer 110 is a Si wafer having a (111), (110), or (100) crystal plane and the temporary wafer T is also a Si wafer having a (100) crystal plane, there is no difference in thermal expansion coefficient during bonding, which contributes to stabilizing the quality of the vertically stacked microdisplay panel.

However, as described above, according to a wafer bonding method, the materials of the support wafer S and/or the temporary wafer T may each be either silicon (Si) or sapphire, and in the case of bonding at room temperature (surface activated bonding) through a surface activation process, wafers of different materials such as silicon (Si) or sapphire may be selected regardless of the thermal expansion coefficient.

Here, the bonding layer 170 may be formed of an opaque conductive material. Specifically, the bonding layer 170 may be formed of any bonded metal, such as AuSn, NiSn, or AuIn, and may also be made of a single material, such as Au—Au or Pt—Pt. It is preferable that the thickness of the bonding layer 170 be smaller, and the bonding layer 170 may include a single layer or a plurality of layers. When the bonding layer 170 includes a plurality of layers, a reflective metal may be formed on the ohmic contact electrode 124 side.

Meanwhile, the bonding layer 170 may include a single layer or a plurality of layers. When the bonding layer 170 includes a plurality of layers, a lower layer may have an absorptive property to block light generated from a lower portion, and an upper layer may have a reflective property to reflect light generated from an upper portion. For example, Ag/Ni may correspond to this. Furthermore, the bonding layer 170 may include an etching mask layer for isolation in an etching operation that will be described below.

As shown in FIGS. 8 and 9, specifically, in the stacking operation S120, for example, in order to form the structure of a positive common electrode 160, a third front wafer 113 in a p-side up form that emits blue light may be bonded to a temporary wafer T (or a separation layer C on the temporary wafer T) through a bonding layer 170, and then a support wafer S of the third front wafer 113 may be removed using LLO or the like. Afterward, a second semiconductor region 1202 of a third light-emitting portion 123 exposed by removing the support wafer S may be etched to reduce a thickness.

Subsequently, a second front wafer 112 in a p-side up form that emits green light may be bonded through the bonding layer 170, and then a support wafer S of the second front wafer 112 may be removed using LLO or the like. Afterward, a second semiconductor region 1202 of a second light-emitting portion 122 exposed by removing the support wafer S may be etched to reduce a thickness.

Subsequently, a first front wafer 111 in a p-side up form that emits red light may be bonded through a bonding layer 170, and then a support wafer S of the first front wafer 111 may be removed using LLO or the like. Afterward, a stack structure may be formed by etching a second semiconductor region 1202 of a first light-emitting portion 121 exposed by removing the support wafer S to reduce a thickness and then forming a first bonding layer 131 on the surface of the second semiconductor region 1202.

Here, a first bonding layer 131 and a second bonding layer 132 that will be described below may be formed of a material capable of eutectic bonding, such as AuSn, below the CMOS heat resistance temperature, or a material capable of solid liquid intermetallic bonding (SIID), such as NiSn, AuIn, CuSn, or AgIn, but are not limited thereto. Furthermore, single material (metal) bonding is also possible, and the thinner the first bonding layer 131 and the second bonding layer 132 are, the more desirable it is.

Subsequently, heat treatment at high temperatures may be optionally performed to improve adhesion of a stack structure. That is, in the present invention, after all RGB light sources are stacked on a support wafer S, high-temperature heat treatment is performed to secure adhesion between RGB epitaxy, and then an RGB stack structure may be bonded to a CMOS Si back wafer 140 at once.

Through this, the temporary wafer T, the separation layer C, the bonding layer 170, the ohmic contact electrode 124, the third light-emitting portion 123, the bonding layer 170, the ohmic contact electrode 124, the second light-emitting portion 122, the bonding layer 170, the ohmic contact electrode 124, the first light-emitting portion 121, and the first bonding layer 131 may be stacked in the vertical direction, and the stack may be selectively subjected to heat treatment at a high temperature, thereby ensuring the strong adhesion between RGB epitaxy.

However, the present invention is not limited to this stacking order, the third light-emitting portion 123, the second light-emitting portion 122, and the first light-emitting portion 121 may be stacked in the vertical direction in the same manner, and various combinations, such as stacking the second light-emitting portion 122, the first light-emitting portion 121, and the third light-emitting portion 123 in that order, are possible.

The bonding operation S130 is an operation of bonding a temporary wafer T in which a plurality of light-emitting portions 120 and a bonding layer 170 are vertically stacked onto a back wafer 140, and then removing the temporary wafer T.

In this case, the bonding in the bonding operation S130 may be performed through opaque conductive metal bonding, such as eutectic bonding between a first bonding layer 131 formed on the temporary wafer T and a second bonding layer 132 formed on the back wafer 140, but is not limited thereto.

After the temporary wafer T and the back wafer 140 are bonded, heat treatment of a bonding layer 130 may be selectively performed at a temperature that does not damage the CMOS circuit of the back wafer 140, and the removal of the temporary wafer T may be performed using an MP technique, a CLO technique, or the like. Meanwhile, when a sapphire temporary wafer T is used as the temporary wafer T, it is of course possible to remove the temporary wafer T using an LLO technique.

Accordingly, when using the first front wafer 111 in a p-side up form, the second front wafer 112 in a p-side up form, and the third front wafer 113 in a p-side up form, the first light-emitting portion 121 for emitting red light, the second light-emitting portion 122 for emitting green light, and the third light-emitting portion 123 for emitting blue light may be sequentially stacked in a p-side up form on the back wafer 140. However, the stacking order of the light-emitting portions 120 is not limited thereto.

In addition, in the case of the use of the first front wafer 111 in an n-side up form, the second front wafer 112 in an n-side up form, and the third front wafer 113 in an n-side up form, the first light-emitting portion 121 emitting red light, the second light-emitting portion 122 emitting green light, and the third light-emitting portion 123 emitting blue light may be sequentially stacked in an n-side up form on the back wafer 140. However, the stacking order of the light-emitting portions 120 is not limited thereto.

The etching operation S140 is an operation of etching a plurality of stacked light-emitting portions 120, an ohmic contact electrode 124, a bonding layer 170, a first bonding layer 131, and a second bonding layer 132 to separate these into preset units, thereby arranging and aligning a plurality of LED stacks L on a plurality of CMOS electrode pads 141.

That is, the etching operation S140 is an operation of vertically etching the plurality of light-emitting portions 120, the ohmic contact electrode 124, the bonding layer 170, the first bonding layer 131, and the second bonding layer 132 until the surface or an adjacent region (for example, a passivation layer) of the back wafer 140 is exposed so that an array is formed, in other words, the plurality of LED stacks L are aligned on upper portions of the aligned CMOS electrode pads 141. Here, the preset unit may mean a pixel or sub-pixel unit, and may mean the width (diameter) of each of a plurality of LED stacks L.

After the above-described etching operation S140 has been performed, each LED stack L disposed on the CMOS electrode pad 141 may have a structure in which a second bonding layer 132, a first bonding layer 131, a first layer, a bonding layer 170, a second layer, a bonding layer 170, a third layer, and a bonding layer 170 are stacked. Here, the first layer may be a first light-emitting portion 121 having an ohmic contact electrode 124 formed on an upper surface, the second layer may be a second light-emitting portion 122 having an ohmic contact electrode 124 formed on an upper surface, and the third layer may be a third light-emitting portion 123 having an ohmic contact electrode 124 formed on an upper surface. However, as described above, the stacking order of the light-emitting portion 120 may vary, and of course, a plurality of layers which are four layers or more may be provided.

The removal operation S150 is an operation of selectively removing the light-emitting portion of each of the LED stacks L.

In the present invention, a plurality of LED stacks L may include a first LED stack L1, a second LED stack L2, and a third LED stack L3. Specifically, in the removal operation S150, third layers of the second LED stack L2 and the first LED stack L1 and a bonding layer 170 on an upper portion of the third layer may be first removed, and then a second layer of the first LED stack L1 and a bonding layer 170 on an upper portion of the second layer may be removed. Afterward, a bonding layer 170 exposed on an upper portion of each LED stack L may be removed to expose an ohmic contact electrode 124.

That is, in the present invention, the second LED stack L2 may have a smaller number of layers than the third LED stack L3, and the first LED stack L1 may have a smaller number of layers than the second LED stack L2. For example, the first LED stack L1 may include only a first layer, and the second LED stack L2 may include a first layer and a second layer, and a bonding layer 170 may be disposed between the first layer and the second layer. Additionally, the third LED stack L3 may include a first layer, a second layer, and a third layer, and bonding layers 170 may be disposed between these layers.

Accordingly, each LED stack L may emit only a specific color by blocking the light generated in a lower light-emitting portion 120 by the bonding layer 170. Specifically, the first LED stack L1 may emit the color of a light-emitting portion 120 of the first layer, the second LED stack L2 may emit the color of a light-emitting portion 120 of the second layer, and the color of a light-emitting portion 120 of the first layer may be blocked by the bonding layer 170. Additionally, the third LED stack L3 may emit the color of a light-emitting portion 120 of the third layer, and the color of the light-emitting portion 120 of the first layer and the color of the light-emitting portion 120 of the second layer may each be blocked by the bonding layer 170.

The forming operation S160 is an operation of forming a mold portion 150 that fills the space between the plurality of aligned LED stacks L, and then forming a common electrode 160 on the plurality of LED stacks L. In this case, when light-emitting portions 120 are in a p-side up form, the common electrode 160 may be formed as a positive electrode, and when the light-emitting portions 120 are in an n-side up form, the common electrode 160 may be formed as a negative electrode.

In this case, preferably, before forming the mold portion 150 that fills the space between the plurality of aligned LED stacks L, a passivation process, that is, a process of covering the side surfaces of all light-emitting portions 120 with an optically transparent and electrically insulating material (for example, SiO2, SiNx, or Al2O3), may be performed.

More specifically, in the forming operation S160, a mold portion 150 may be formed between and above the plurality of aligned LED stacks L, the mold portion 150 may be etched so that upper ohmic contact electrodes 124 of the plurality of LED stacks L are exposed, and then a common electrode 160 may be formed to be connected to the upper portions of the plurality of LED stacks L, thereby completing the vertically stacked LEDoS structure. Here, the common electrode 160 may be formed of a material having transparent conductivity similar to the ohmic contact electrode 124, when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO.

Additionally, the surface of the common electrode 160 may also be polished to a smooth flat surface through MP or CMP.

Furthermore, although not shown, a protective layer made of a transparent organic material may be additionally formed to protect the common electrode 160 from the atmospheric environment.

Hereinafter, a vertically stacked microdisplay panel 100 according to one embodiment of the present invention will be described in detail with reference to the attached drawings.

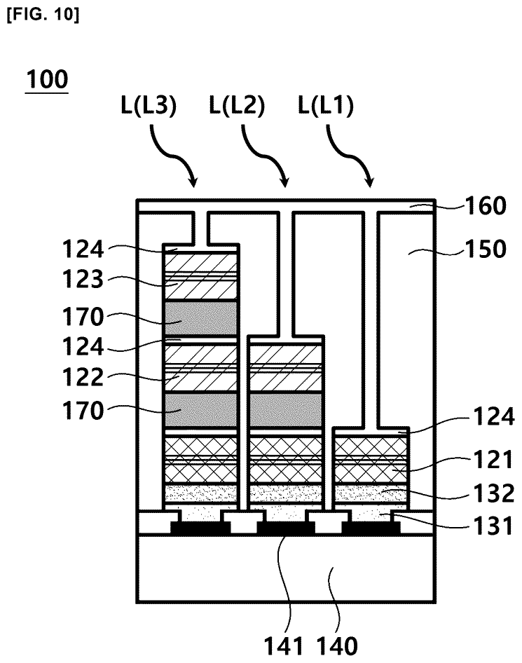

FIG. 10 shows a vertically stacked microdisplay panel according to one embodiment of the present invention.

As shown in FIG. 10, the vertically stacked microdisplay panel 100 according to one embodiment of the present invention may include a back wafer 140, a plurality of LED stacks L, a mold portion 150, and a common electrode 160.

Hereinafter, some of the overlapping content with the method S100 of manufacturing a vertically stacked microdisplay panel according to one embodiment of the present invention will be omitted.

The back wafer 140 is an active driving IC driven by an AM method, and is a CMOS wafer in which a plurality of CMOS electrode pads 141 are arranged on an upper surface in an array. A passivation layer may be formed on an upper surface of the back wafer 140, and a portion of the passivation layer may be etched so that the plurality of CMOS electrode pads 141 are exposed when bonding a front wafer 110.

The plurality of LED stacks L may each include at least one light-emitting portion 120 having an ohmic contact electrode 124 on an upper surface and may be aligned on a plurality of CMOS electrode pads 141.

In the present invention, the plurality of LED stacks L may include a first LED stack L1, a second LED stack L2, and a third LED stack L3. The second LED stack L2 may have a smaller number of layers than the third LED stack L3, and the first LED stack L1 may have a smaller number of layers than the second LED stack L2. For example, the first LED stack L1 may include only a first layer, the second LED stack L2 may include a first layer and a second layer, and a bonding layer 170 may be disposed between the first layer and the second layer. Additionally, the third LED stack L3 may include a first layer, a second layer, and a third layer, and bonding layers 170 may be disposed between these layers.

Here, the first layer may be a first light-emitting portion 121 having an ohmic contact electrode 124 formed on an upper surface, the second layer may be a second light-emitting portion 122 having an ohmic contact electrode 124 formed on an upper surface, and the third layer may be a third light-emitting portion 123 having an ohmic contact electrode 124 formed on an upper surface, but as described above, the stacking order of the light-emitting portions 120 may vary.

Accordingly, each LED stack L may emit only a specific color by blocking the light generated from the lower light-emitting portion 120 by the bonding layer 170. Specifically, the first LED stack LI may emit the color of the light-emitting portion 120 of the first layer, the second LED stack L2 may emit the color of the light-emitting portion 120 of the second layer, and the color of the light-emitting portion 120 of the first layer may be blocked by the bonding layer 170. Additionally, the third LED stack L3 may emit the color of the light-emitting portion 120 of the third layer, and the color of the light-emitting portion 120 of the first layer and the color of the light-emitting portion 120 of the second layer may each be blocked by the bonding layer 170.

The mold portion 150 supports the vertically stacked LEDoS structure and may be formed to fill the space between the plurality of aligned LED stacks L.

In the present invention, the light-emitting portions 120 of the LED stack L may be stacked in a p-side up form or an n-side up form, and accordingly, the common electrode 160 may be formed as a positive electrode or a negative electrode and may be formed on the plurality of LED stacks L on which the mold portion 150 is formed. Here, when the common electrode 160 is a positive electrode, the material of the common electrode 160 may include NiO, PtO, PdO, AgO2, Au, Rh2O3, RuO2, In2O3, SnO2, ZnO, IZO, ITO, and IGZO, and when the common electrode 160 is a negative electrode, the material of the common electrode 160 may include TiN, CrN, VN, In2O3, SnO2, ZnO, IZO, ITO, and IGZO.

According to the present invention, since a color filter is unnecessary despite the adoption of a vertically stacked tandem structure, the color quality of a microdisplay can be significantly improved, and process complexity and productivity can be significantly improved.

Also, according to the present invention, unlike the existing monolithic integration method or hybridization method having alignment issues, an engineering monolithic epitaxy wafer is first manufactured, and then a stack on the engineering monolithic epitaxy wafer is etched to separate the stack into preset units, thereby allowing a plurality of LED stacks to be aligned on a plurality of CMOS electrode pads. Thus, not only a small-diameter wafer of 6 inches or less but also a large-diameter wafer of 8 inches or more can be used so that the product yield can be significantly increased.

Additionally, according to the present invention, a vertically stacked tandem structure can be formed by general metal bonding.

In addition, according to the present invention, since the stacking order of a light-emitting portion is not limited, there is an effect of being able to adjust the red light-emitting portion or the like, which has the lowest light-emitting efficiency, to the top layer.

Meanwhile, the effects of the present invention are not limited to the above-described effects, and various effects that are apparent to those skilled in the art within the scope that is obvious from the description below may also be included.

Above, all components comprising embodiments of the present invention have been described as being combined or operating in combination, but the present invention is not necessarily limited to these embodiments. In other words, any of the components may optionally operate in combination with one or more of the foregoing, provided that it is within the scope of the present invention.

In addition, terms such as “includes,” “consists of,” or “has” as used herein shall, unless specifically indicated to the contrary, be construed to mean that the component may be inherent in, and therefore may further include, other components, rather than exclude, other components. All terms, including technical or scientific terms, unless otherwise defined, shall have the same meaning as commonly understood by one of ordinary skill in the art to which the present invention belongs. Commonly used terms, such as dictionary-defined terms, are to be interpreted consistent with their contextual meaning in the relevant art and are not to be construed in an idealized or overly formal sense unless expressly defined by the present invention.

And the foregoing description is merely an exemplary description of the technical ideas of the present invention, and various modifications and variations will be apparent to one having ordinary knowledge in the technical field to which the present invention belongs, without departing from the essential features of the present invention.

Accordingly, the embodiments disclosed in the present invention are intended to describe and not to limit the technical ideas of the present invention, and the scope of the technical ideas of the present invention is not limited by these embodiments. The scope of protection of the present invention shall be construed in accordance with the following claims, and all technical ideas within the equivalent scope shall be construed as falling within the scope of the present invention.

What is claimed is:

1. A vertically stacked microdisplay panel comprising:
a back wafer in which a plurality of complementary metal-oxide semiconductor (CMOS) electrode pads are aligned on an upper surface;
a plurality of light-emitting diode (LED) stacks, each of which includes at least one light-emitting portion and is aligned on a corresponding one of the plurality of CMOS electrode pads; and
a common electrode formed on the plurality of LED stacks,
wherein, when the LED stacks include the plurality of light-emitting portions, the plurality of light-emitting portions are bonded through a bonding layer and stacked in a vertical direction, and
when the plurality of light-emitting portions are bonded through the bonding layer, each of the LED stacks emits only a specific color by blocking light generated from a lower light-emitting portion with the bonding layer.

2. The vertically stacked microdisplay panel of claim 1, wherein the bonding layer is formed of an opaque conductive material.

3. The vertically stacked microdisplay panel of claim 2, wherein the plurality of LED stacks include a first LED stack for emitting only a first color, a second LED stack for emitting only a second color, and a third LED stack for emitting only a third color.

4. The vertically stacked microdisplay panel of claim 1, wherein the common electrode is a positive electrode or a negative electrode.

5. A method of manufacturing a vertically stacked microdisplay panel, comprising:
a preparation operation of preparing a plurality of front wafers including a support wafer and a light-emitting portion, a temporary wafer, and a back wafer in which a plurality of CMOS electrode pads are aligned on an upper surface;
a stacking operation of vertically stacking the plurality of light-emitting portions on the temporary wafer by repeatedly performing bonding of the front wafer onto the temporary wafer through a bonding layer and then removing the support wafer;
a bonding operation of bonding the plurality of stacked light-emitting portions onto the back wafer and then stacking the plurality of light-emitting portions on the back wafer by removing the temporary wafer;
an etching operation of separating the plurality of stacked light-emitting portions into predetermined units by etching the plurality of light-emitting portions to align a plurality of light-emitting diodes (LEDs) on the plurality of CMOS electrode pads;
a removal operation of selectively removing the light-emitting portion of each of the LED stacks; and
a forming operation of forming a common electrode on the plurality of LED stacks,
wherein, when the plurality of light-emitting portions are bonded through the bonding layer, each of the LED stack emits only a specific color by blocking light generated from a lower light-emitting portion with the bonding layer.

6. The method of claim 5, wherein the bonding layer is formed of an opaque conductive material.

7. The method of claim 6, wherein the plurality of LED stacks include a first LED stack for emitting only a first color, a second LED stack for emitting only a second color, and a third LED stack for emitting only a third color.

8. The method of claim 5, wherein the common electrode is a positive electrode or a negative electrode.
